(19) United States
(12) Patent Application Publication
(10) Pub. No.: US 2025/0316610 A1
(43) Pub. Date: Oct. 9, 2025

(54) ALIGNMENT KEY FOR OVERLAY INSPECTION AND INSPECTION DEVICE INCLUDING THE ALIGNMENT KEY

(71) Applicant: SAMSUNG ELECTRONICS CO., LTD., Suwon-si (KR)

(72) Inventors: Seunghoon HAN, Suwon-si (KR); Heejin CHOI, Suwon-si (KR); Changgyun SHIN, Suwon-si (KR); Junghyun PARK, Suwon-si (KR); Kyuhwan CHOI, Suwon-si (KR); Hyeonsoo PARK, Suwon-si (KR)

(73) Assignee: SAMSUNG ELECTRONICS CO., LTD., Suwon-si (KR)

(21) Appl. No.: 19/022,250

(22) Filed: Jan. 15, 2025

(30) Foreign Application Priority Data
Apr. 3, 2024 (KR) 10-2024-0045574

(51) Int. Cl. H01L 23/544; H01L 21/68

(52) U.S. Cl. CPC H01L 23/544; H01L 21/681; H01L 2223/54426

(57) ABSTRACT

An alignment key configured to form an optical interference pattern by using incident light, may include a first substrate, a first pattern layer including a plurality of first gratings disposed on the first substrate, the plurality of first gratings being regularly arranged at a first pitch that is less than a wavelength of the incident light, and a second pattern layer disposed to face the first pattern layer and including a plurality of second gratings. The plurality of second gratings may be regularly arranged at a second pitch that is different from the first pitch and less than the wavelength of the incident light, in the same arrangement direction as the plurality of first gratings.

### CROSS-REFERENCE TO RELATED APPLICATION

This application claims priority to Korean Patent Application No. 10-2024-0045574, filed on Apr. 3, 2024, in the Korean Intellectual Property Office, the disclosure of which is incorporated herein in its entirety by reference.

### BACKGROUND

### 1. Field

The disclosure relates to creating and using an alignment key for conducting overlay inspection in a multi-layered manufacturing process of semiconductor fabrication.

### 2. Description of the Related Art

As a degree of integration of various integrated circuit devices including a memory, a driving integrated circuit (IC), a logic device, an image sensor, etc. continues to increase, the sizes of electronic components provided in IC devices have reduced accordingly.

The electronic components formed in different substrates may be packaged together using an alignment mark provided in each substrate.

Furthermore, a post bonding inspection (PBI) key may be provided on each substrate for post bonding inspection, and as the existing PBI keys have structures at a micron scale, there is a limit in inspection precision. Accordingly, in accordance with the scale down of electronic components, a new method to improve inspection precision may be required.

### SUMMARY

One or more embodiments of the present application provide an alignment key configured for high-precision overlay inspection to meet the scale down of electronic components.

According to an aspect of the disclosure, an alignment key configured to form an optical interference pattern by using incident light. The alignment key may include: a first substrate; a first pattern layer including a plurality of first gratings disposed on the first substrate, wherein the plurality of first gratings are regularly arranged at a first pitch that is less than a wavelength of the incident light; and a second pattern layer disposed to face the first pattern layer and including a plurality of second gratings, wherein the plurality of second gratings are regularly arranged at a second pitch that is different from the first pitch and less than the wavelength of the incident light, in a same arrangement direction as the plurality of first gratings.

Each of the plurality of first gratings and the plurality of second gratings is a line grating that extends linearly in a direction perpendicular to the arrangement direction of the plurality of first gratings and the plurality of second gratings. The first pitch of the plurality of first gratings and the second pitch of the plurality of second gratings are each equal to or less than ½ of the wavelength of the incident light.

A width of each of the plurality of first gratings in the second direction is same as a width of each of the plurality of second gratings in the second direction.

The first substrate includes grooves recessed from a surface of the first substrate and corresponding to a reverse shape of the plurality of first gratings, and the plurality of first gratings are disposed within the grooves.

The plurality of first gratings or the plurality of second gratings include a metal material.

The plurality of second gratings are disposed on a second substrate having one surface in contact with the first substrate.

The second substrate includes grooves recessed from the one surface and corresponding to a reverse shape of the plurality of second gratings, and the plurality of second gratings are disposed within the grooves

The plurality of second gratings are entirely buried inside the second substrate.

A distance which the plurality of second gratings are separated from the one surface is λ/(2*n) or less, where λ is the wavelength of the incident light and n is a refractive index of the second substrate.

The alignment key may further include a metastructure layer disposed between the plurality of second gratings and the one surface and including a plurality of nanostructures.

Each of the plurality of nanostructures has a cylindrical shape with a diameter less than a width of each of the plurality of first gratings and each of the plurality of second gratings.

An arrangement pitch of the plurality of nanostructures is less than each of the first pitch and the second pitch.

The second pattern layer is supported by the first substrate and disposed apart from the first pattern layer.

The alignment key may further include a dielectric layer disposed between the first pattern layer and the second pattern layer.

The first pattern layer is buried to a certain depth from one surface of the first substrate, and the second pattern layer is disposed on the one surface.

Each of the plurality of first gratings includes a metal material, and each of the plurality of second gratings includes a photoresist material.

Each of the plurality of first gratings and the plurality of second gratings extends linearly in a first direction, the plurality of first gratings are repeatedly arranged in a second direction perpendicular to the first direction, and the first pattern layer and the second pattern layer are disposed to face each other is a third direction perpendicular to the first direction and the second direction. Based on the first pattern layer and the second pattern layer facing each other in the third direction being a first group, the alignment key further includes a second group adjacent to the first group in the first direction or the second direction. The second group has a configuration obtained by rotating the first group by 90° on a plane perpendicular to the third direction.

Each of the plurality of first gratings and the plurality of second gratings extends linearly in a first direction, the plurality of first gratings are repeatedly arranged in a second direction perpendicular to the first direction, and the first pattern layer and the second pattern layer are disposed to face each other is a third direction perpendicular to the first direction and the second direction. The first pattern layer further includes a plurality of third line gratings each having a longitudinal direction in the first direction, and regularly arranged in the second direction at the second pitch. The second pattern layer further includes a plurality of fourth gratings each having a longitudinal direction in the first direction, and regularly arranged in the second direction at the first pitch. Based on the first pattern layer and the second pattern layer facing each other in the third direction being a first group, the alignment key further includes a second group adjacent to the first group in the first direction or the second direction, and the second group has a configuration obtained by rotating the first group by 90° on a plane perpendicular to the third direction.

According to another aspect of the disclosure, an inspection device may include: a light source; an alignment key on which light emitted from the light source is incident; an imaging device configured to measure an optical interference pattern formed through an interaction between the light and the alignment key; and a processor configured to analyze a measurement result of the imaging device, wherein the alignment key includes a top bonding plate and a bottom bonding plate, each of the top bonding plate and the bottom bonding plate including a plurality of metal-based gratings, and wherein the plurality of metal-based gratings on the top bonding plate has a first pitch, and plurality of metal-based gratings on the bottom bonding plate has a second pitch, the first pitch and the second pitch being different from each other and each of the first pitch and the second pitch being less than half a wavelength of the incident light.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic cross-sectional view showing the structure of an alignment key according to one or more embodiments;

FIGS. 2A and 2B are plan views respectively showing a first pattern layer and a second pattern layer provided in an alignment key according to one or more embodiments;

FIG. 3 shows an example of a moiré pattern formed by an alignment key according to one or more embodiments;

FIG. 4 is a schematic cross-sectional view showing the structure of an alignment key according to one or more embodiments;

FIG. 5 is a schematic cross-sectional view showing the structure of an alignment key according to one or more embodiments.

FIGS. 6A, 6B, and 6C are plan views respectively showing a first pattern layer, a metastructure layer and a second pattern layer, provided in the alignment key of FIG. 5.

FIG. 7 shows an example of a moiré pattern formed by the alignment key of FIGS. 6A, 6B, and 6C;

FIG. 8 is a schematic cross-sectional view showing the structure of an alignment key according to one or more embodiments;

FIG. 9 is a schematic cross-sectional view showing the structure of an alignment key according to one or more embodiments;

FIG. 10 is a schematic cross-sectional view showing the structure of an alignment key according to one or more embodiments;

FIG. 11 is a schematic cross-sectional view showing the structure of an alignment key according to one or more embodiments;

FIG. 12 is a plan view of an alignment key according to one or more embodiments;

FIG. 13 is a plan view of an alignment key according to one or more embodiments;

FIG. 14 is a graph showing an example of the performance of an alignment key according to one or more embodiments according to a difference between the pitch of a first pattern layer and the pitch of a second pattern layer; and

FIG. 15 is a schematic block diagram showing the structure of an inspection device according to one or more embodiments.

### DETAILED DESCRIPTION

Example embodiments are described in greater detail below with reference to the accompanying drawings.

In the following description, like drawing reference numerals are used for like elements, even in different drawings. The matters defined in the description, such as detailed construction and elements, are provided to assist in a comprehensive understanding of the example embodiments. However, it is apparent that the example embodiments can be practiced without those specifically defined matters. Also, well-known functions or constructions are not described in detail since they would obscure the description with unnecessary detail.

Hereinafter, when a constituent element is disposed “above” or “on” to another constituent element, the constituent element may include not only an element directly contacting and disposed on the other constituent element, but also an element disposed above the other constituent element in a non-contact manner.

Terms such as “first” and “second” are used herein merely to describe a variety of constituent elements, but the constituent elements are not limited by the terms. Such terms are used only for the purpose of distinguishing one constituent element from another constituent element.

As used herein, the singular forms “a,” “an,” and “the” are intended to include the plural forms as well, unless the context clearly indicates otherwise. Furthermore, it will also be understood that the terms “comprises,” “includes,” and “has” used herein specify the presence of stated elements, but do not preclude the presence or addition of other elements, unless otherwise defined.

Furthermore, terms such as “ . . . portion,” “ . . . unit,” “ . . . module,” and “ . . . block” stated in the disclosure may signify a unit to process at least one function or operation and the unit may be embodied by hardware, software, or a combination of hardware and software.

The use of terms “a,” “an,” “the,” and similar referents in the context of describing the disclosure are to be construed to cover both the singular and the plural.

Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, all of a, b, and c, or any variations of the aforementioned examples.

The steps of all methods described herein can be performed in any suitable order unless otherwise indicated herein or otherwise clearly contradicted by context. Furthermore, the use of any and all examples, or language (e.g., “such as”) provided herein, is intended merely to better illuminate the disclosure and does not pose a limitation on the scope of the disclosure unless otherwise claimed.

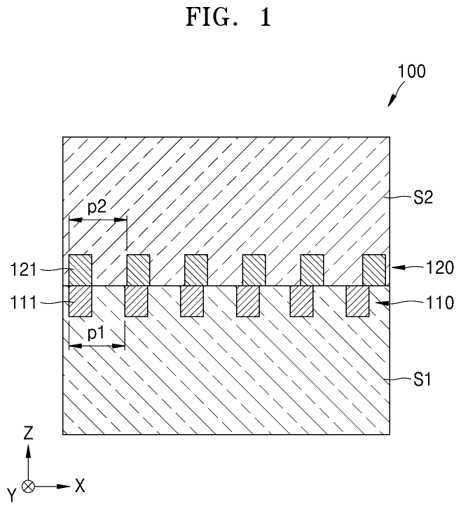

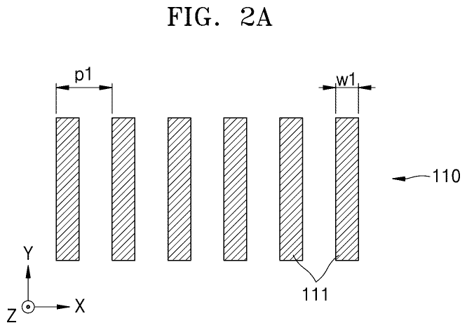

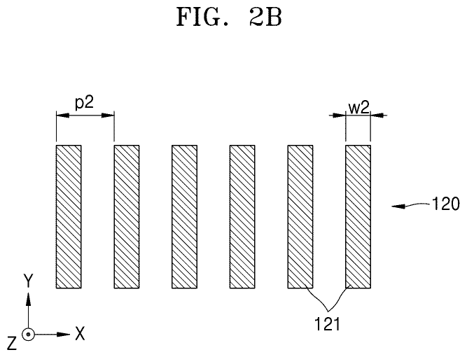

FIG. 1 is a schematic cross-sectional view showing the structure of an alignment key 100 according to one or more embodiments. FIGS. 2A and 2B are plan views respectively showing a first pattern layer 110 and a second pattern layer 120 provided in the alignment key 100 according to one or more embodiments.

The alignment key 100 may measure an overlay by analyzing an optical inference pattern (e.g., a moiré pattern) formed by incident light. The alignment key 100 may include the first pattern layer 110 and the second pattern layer 120, which are arranged to face each other and have different, but similar pitches (arrangement pitch). For example, the difference between the pitch of gratings in the first pattern layer 110 and the pitch of gratings in the second pattern layer 120 may be less than a predetermined threshold, allowing the gratings in the first pattern layer 110 to overlap with those in the second pattern layer 120. Here, the first pattern layer 110 and the second pattern layer 120 may be also referred to as a top bonding plate and a bottom bonding plate, respectively.

The first pattern layer 110 may include a plurality of first line gratings 111. The first line gratings 111 may each have a length in a first direction (Y direction) and a width w1 in a second direction (X direction), and may be repeatedly arranged in the second direction. The first line gratings 111 may be regularly arranged at a first pitch p1. The width w1 of each of the first line gratings 111 may be a sub-wavelength. The width w1 of the first line gratings 111 may be less than the wavelength of incident light used for forming a moiré pattern, and may be, for example, equal to or less than ½ of the wavelength.

The second pattern layer 120 may include a plurality of second line gratings 121. The second line gratings 121 may have a length in the first direction (Y direction) and a width w2 in the second direction (X direction), and may be repeatedly arranged in the second direction. The second line gratings 121 may be regularly arranged at a second pitch p2. The width w2 of each of the second line gratings 121 may be a sub-wavelength, for example, equal to or less than ½ of the wavelength of incident light.

The second pitch p2 differs from the first pitch p1. Although the second pitch p2 is illustrated to be greater than the first pitch p2 in the drawings, this is merely an example and the first pitch p1 may be greater than the second pitch p2. The first pitch p1 and the second pitch p2 may be sub-wavelengths, and may be, for example, equal to or less than ½ of the wavelength of light used for inspection.

The second pattern layer 120 may be arranged to face the first pattern layer 110, for example, in a third direction (Z direction). The width w2 of each of the second line gratings 121 may be the same as the width w1 of each of the first line gratings 111. However, the disclosure is not limited thereto, and the widths w1 and w2 may be different from each other.

In FIGS. 1, 2A, and 2B, the width w1 of each of the first line gratings 111 and the width w2 of each of the second line gratings 121 are the same, while the first pitch p1 and the second pitch p2 are different from each other, and one of the first line gratings 111 located on the leftmost in the first pattern layer 110 and one of the second line gratings 112 located on the leftmost in the second pattern layer 120 are illustrated to be arranged to be completely overlapped. However, this is an example. One of the first line gratings 111 and one of the second line gratings 121 respectively located at different positions, for example, at the center portion or on the right may be arranged to be completely overlapped with each other. In FIG. 1, the numbers of the first line gratings 111 and the second line gratings 112, and the locations or numbers of the first line gratings 111 and the second line gratings 112 which are overlapped with each other are examples. In order to allow a moiré pattern pitch (p1*p2/|p1−p2|) to occur once or more, the numbers and arrangements of the first line gratings 111 and the second line gratings 112 may be determined.

The first pattern layer 110 may be provided in a first substrate S1. The first line gratings 111 of the first pattern layer 110 may be disposed such that an upper surface of the first pattern layer 110 and an upper surface of the first substrate S1 form the same surface. As illustrated, the first substrate S1 may have grooves corresponding to the reverse shape of the first line gratings 111, which are recessed from the surface of the first substrate S1, and the first line gratings 111 may be disposed in the grooves.

The second pattern layer 120 may be provided in a second substrate S2. The second substrate S2 may be in contact with the first substrate S1. The second line gratings 121 of the second pattern layer 120 may be disposed such that the lower surface of the second pattern layer 120 and the lower surface of the second substrate S2 form the same surface. As illustrated, the second substrate S2 may have grooves corresponding to the reverse shape of the second line gratings 121, which are recessed from the surface of the second substrate S2, and the second line gratings 121 may be disposed in the grooves.

In such an arrangement, the first line gratings 111 and the second line gratings 121 may be positioned directly opposite each other, come into contact with each other, and thus, a separation distance between the first pattern layer 110 and the second pattern layer 120 in the third direction (Z direction) may be 0. However, this is a mere example, and the first pattern layer 110 and the second pattern layer 120 may have a certain separation distance in the third direction (Z direction).

One of the first pattern layer 110 and the second pattern layer 120 may include a metal material. The first pattern layer 110 and the second pattern layer 120 may both include a metal material, or any one thereof may include a metal material, while the other may include a dielectric material.

The first substrate S1 and the second substrate S2 may each include device layers to be combined with each other, in addition to the first pattern layer 110 and the second pattern layer 120. The device layers may include, for example, an insulating pattern, a semiconductor pattern, a metal pattern, or the like, and may be a part of a memory device, a logic device, an image sensor, an integrated circuit device, or the like. The device layers are not separately illustrated in the following drawings.

The metal material having a sub-wavelength dimension and included in the first pattern layer 110 or the second pattern layer 120 may operate as a high refractive index meta material based on surface plasmon and may transmit a pattern of light of a diffraction limit. As such, the transmitted light may pass through the first pattern layer 110 or the second pattern layer 120, which is a meta structure having a different pitch arranged adjacent thereto, and form a moiré pattern. By analyzing the moiré pattern, whether there is an alignment of the first substrate S1 and the second substrate S2, that is, an overlay or alignment between two device layers provided in the first substrate S1 and the second substrate S2 and to be combined with each other, may be analyzed. Such analysis may be referred to as a post bonding inspection (PBI).

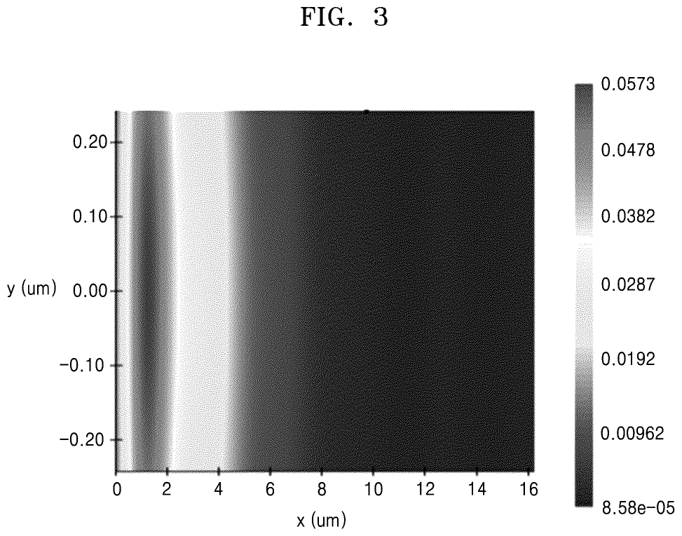

FIG. 3 shows an example of a moiré pattern formed by an alignment key according to one or more embodiments.

FIG. 3 illustrates one moiré pattern pitch imaged to a camera when p1 is 560 nm, p2 is 580 nm, and the wavelength of incident light is 1.2 μm. FIG. 3 shows pattern properties with respect to an area at a level of 0.5 μm in the Y direction, and an actual key structure is not limited to the configuration as above.

A pitch of a moiré pattern (moiré pitch) formed when parallel light is radiated to an alignment key according to one or more embodiments is (p1+p2)/|p1−p2|. Due to a moiré effect, a gain that amplifies an overlay change to a movement of the moiré pattern is p1/|p1−p2| or p2/|p1−p2| depending on locations of an incident surface of illumination light and the location of an imaging module.

When p1 is 560 nm and p2 is 580 nm, the moiré pattern pitch is 16.2 μm and the gain is 29. Such a moiré pattern may allow precise measurement of an overlay. For example, when imaging is made using a microscope optical camera including an image sensor having a pixel resolution of 0.144 μm, a resolution of about 5 nm may be secured.

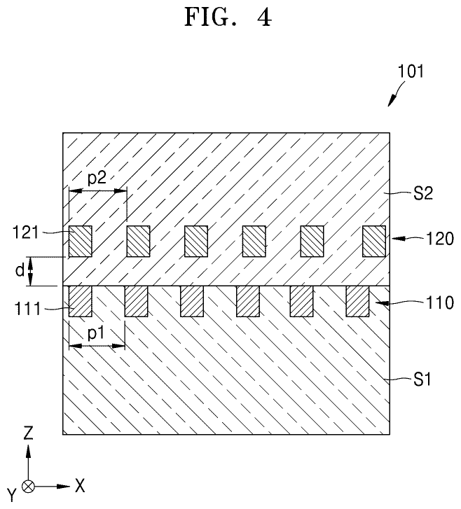

FIG. 4 is a schematic cross-sectional view showing the structure of an alignment key 101 according to one or more embodiments.

The alignment key 101 according to the present embodiment differs from the alignment key 100 of FIG. 1 in that the second pattern layer 120 is entirely buried inside the second substrate S2.

The first pattern layer 110 and the second pattern layer 120 are separated from each other in the third direction (Z direction) and have a separation distance d. Assuming that the wavelength of incident light is λ and the refractive index of the second substrate S2 is n, the separation distance d may be λ/(2*n) or less.

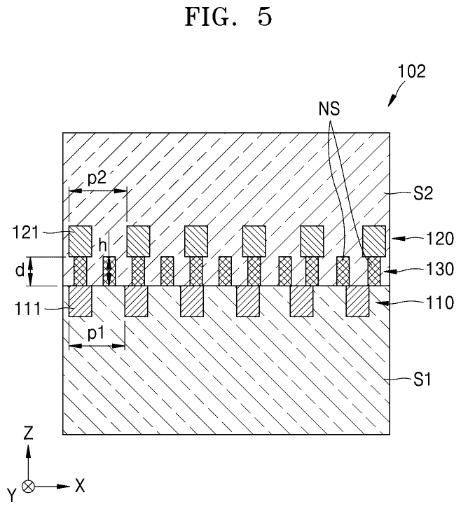

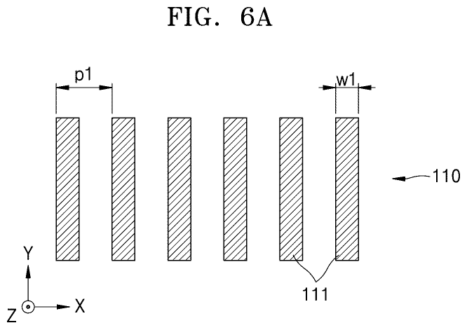

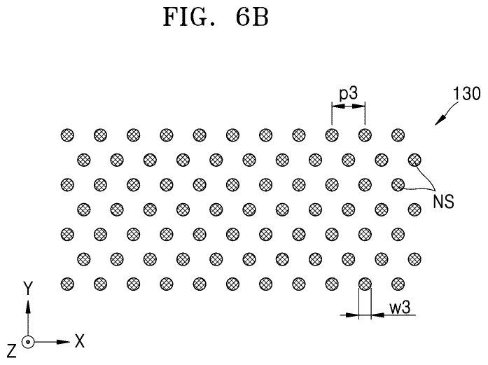

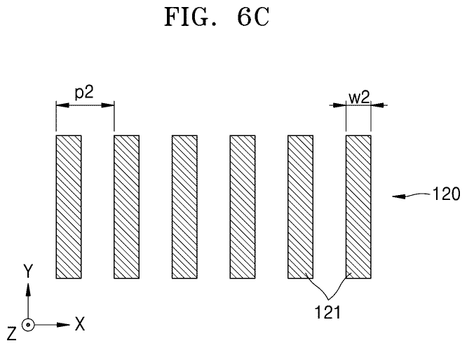

FIG. 5 a schematic cross-sectional view showing the structure of an alignment key 102 according to one or more embodiments, and FIGS. 6A, 6B, and 6C are plan views respectively showing the first pattern layer 110, a metastructure layer 130, and the second pattern layer 120 provided in the alignment key 102 of FIG. 5.

The alignment key 102 according to the present embodiment differs from the alignment key 101 of FIG. 4 in that the former further includes the metastructure layer 130 between the first pattern layer 110 and the second pattern layer 120. The metastructure layer 130 may have a metastructure composed of a plurality of nanostructures, each having a high refractive index (e.g., a refractive index of 1.5 or greater) or a metal (e.g., Cu, TiN, Al, etc.) or composition of several metals.

A plurality of nanostructures NS may be disposed within the separation distance d in which the second pattern layer 120 is separated from the surface of the second substrate S2 in a depth direction. The nanostructures NS may be arranged two-dimensionally in the first direction and the second direction. As illustrated, the nanostructures NS may form a hexagonal grid arrangement or a rectangular grid arrangement.

Each of the nanostructures NS may include a metal or a high refractive index material. Each of the nanostructures NS may include Cu, W, TiN, or other various metal materials, or c-Si, p-Si, a-Si, III-V compound semiconductors (GaAs, GaP, GaN, etc.), SiC, TiO2, or SiN.

The nanostructures NS may each have a cylindrical shape having a diameter w3 that is less than the width w1 of each of the first line gratings 111 and the width w2 of each of the second line gratings 121. The cylindrical shape is an example, and the nanostructures NS may each have a polygonal column shape or an oval column shape.

A height h of each of the nanostructures NS may be the same as the separation distance d in which the second line gratings 121 is separated from a lower surface of the second substrate S2. An arrangement pitch p3 of the nanostructures NS may be less than the first pitch p1 and the second pitch p2. The arrangement pitch p3 of each of the nanostructures NS may be equal to or less than ½ of the first pitch p1 or equal to or less than ½ of the second pitch p2.

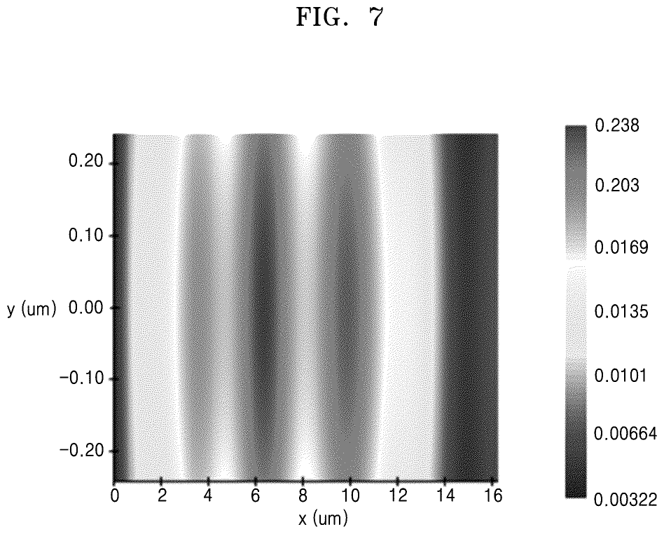

FIG. 7 shows an example of a moiré pattern formed by the alignment key of FIGS. 6A, 6B, and 6C.

When p1 is 560 nm, p2 is 580 nm, and the wavelength of incident light is 1.2 μm, due to a high refractive index effect of the metastructure layer, the moiré pattern of FIG. 7 may have a complicated shape compared with the moiré pattern of FIG. 3 in which no metastructure layer exists. FIG. 7 shows pattern properties with respect to an area at a level of moiré pattern one pitch in the X direction and 0.5 μm in the Y direction, and an actual key structure is not limited to the configuration as above.

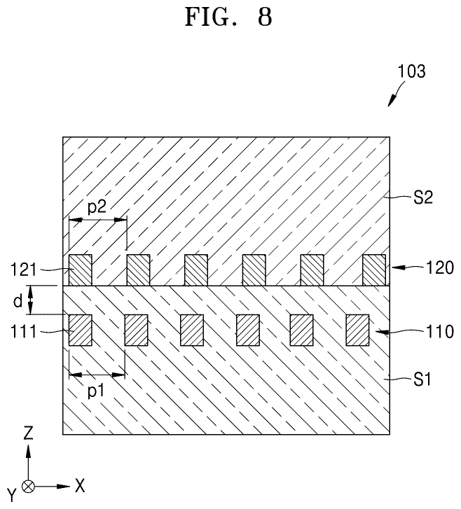

FIG. 8 is a schematic cross-sectional view showing the structure of an alignment key 103 according to one or more embodiments.

The alignment key 103 according to the present embodiment differs from the alignment key 100 of FIG. 1 in that the first pattern layer 110 is entirely buried inside the first substrate S1.

The first pattern layer 110 and the second pattern layer 120 are separated from each other in the third direction by the separation distance d. Assuming that the wavelength of incident light is λ and the refractive index of the first substrate S1 is n, the separation distance d may be λ/(2*n) or less.

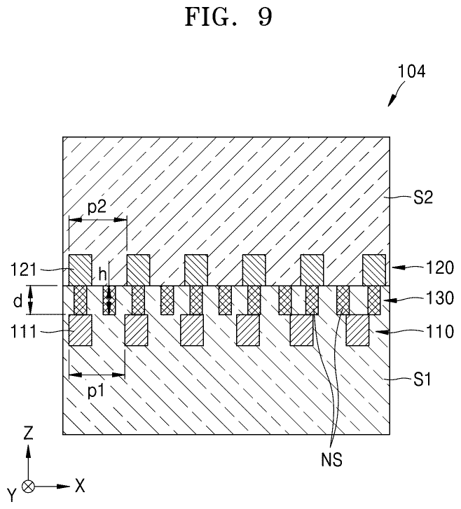

FIG. 9 is a schematic cross-sectional view showing the structure of an alignment key 104 according to one or more embodiments.

The alignment key 104 according to the present embodiment differs from the alignment key 103 of FIG. 9 in that the former further includes the metastructure layer 130 between the first pattern layer 110 and the second pattern layer 120. In other words, the nanostructures NS may be disposed within the separation distance d in which the first pattern layer 110 is separated from the surface of the first substrate S1 in the depth direction.

The nanostructures NS may be similar to that described with reference to FIG. 6B. In other words, the nanostructures NS may each include a metal or a high refractive index material, and have cylindrical shape having the diameter w3 that is less than the width w1 of each of the first line gratings 111 and the width w2 of each of the second line gratings 121. The height of each of the nanostructures NS may be the same as the separation distance in which the second line gratings 121 is separated from the upper surface of the first substrate S1, and the arrangement pitch p3 of the nanostructures NS may be may be less than the first pitch p1 and the second pitch p2.

Each of the alignment keys 100, 101, 102, 103, and 104 described above, in which the first pattern layer 110 and the second pattern layer 120 are divided and arranged in the first substrate S1 and the second substrate S2, may be used for alignment inspection after the first substrate S1 and the second substrate S2 are bonded to each other, that is, post bonding inspection.

The alignment keys according to some embodiments may be used for an inspection after photolithography process and an after development inspection (ADI). Examples thereof are described below.

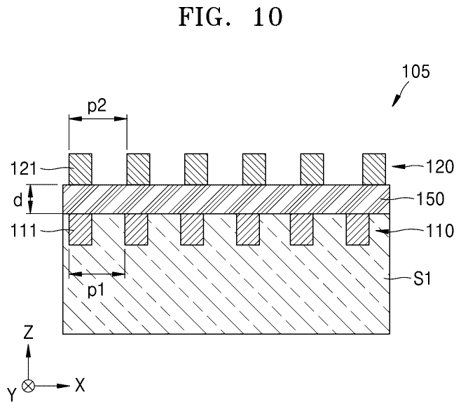

FIG. 10 is a schematic cross-sectional view showing the structure of an alignment key 105 according to one or more embodiments.

The alignment key 105 according to the present embodiment may include the first pattern layer 110 on the first substrate S1, a dielectric layer 150 on the first pattern layer 110, and the second pattern layer 120 on the dielectric layer 150.

The thickness of the dielectric layer 150, that is, the separation distance d between the first pattern layer 110 and the second pattern layer 120 may be λ/(2*n) or less, assuming that the wavelength of incident light is λ and the refractive index of the dielectric layer 150 is n.

The first line gratings 111 constituting the first pattern layer 110 may include a metal material. The second line gratings 121 constituting the second pattern layer 120 may include a photoresist material. The second pattern layer 120 may be formed during the photolithography process performed when manufacturing a device layer on the first substrate S1.

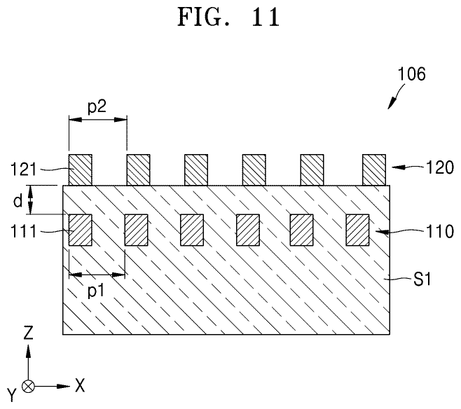

FIG. 11 is a schematic cross-sectional view showing the structure of an alignment key 106 according to one or more embodiments.

The alignment key 106 according to the present embodiment differs from the alignment key 105 of FIG. 10 in that the first pattern layer 110 is buried at a certain depth from the surface of the first substrate S1 such that the separation distance d between the first pattern layer 110 and the second pattern layer 120 is formed.

According to the descriptions presented above, in the first pattern layer 110 and the second pattern layer 120 provided in each of the alignment keys 100, 101, 102, 103, 104, 105, and 106 used for PBI or ADI, the first line gratings 111 and the second line gratings 121 are respectively arranged in the second direction (X direction) with a longitudinal direction thereof being in the first direction (Y direction), thereby inspecting an overlay in the second direction.

In a modified embodiment, in order to inspect an overlay in the first direction (Y direction), the alignment keys may include line gratings arranged in the first direction (Y direction) with a longitudinal direction thereof being in the second direction (X direction).

Furthermore, in another modified embodiment, in order to inspect both of an overlay in the first direction and an overlay in the second direction, line gratings arranged in two types of arrangement directions may be included in the alignment key.

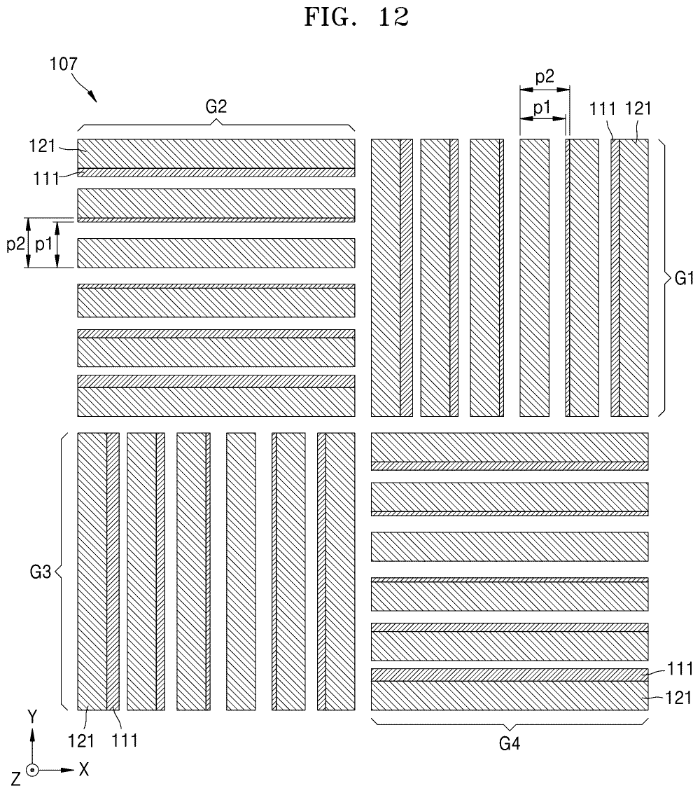

FIG. 12 is a plan view of an alignment key 107 according to one or more embodiments.

The alignment key 107 according to the present embodiment may be used for PBI or ADI, and in the drawing, while the configuration of the first substrate S1, the second substrate S2, and the dielectric layer 150 is omitted, only two pattern layers arranged to face each other in the third direction (Z direction) are illustrated.

The alignment key 107 may include a first group G1. The first group G1 may include, as illustrated in FIG. 1, a first pattern layer including the first line gratings 111 and a second pattern layer including the second line gratings 121. In other words, the first line gratings 111 each have the length in the first direction (Y direction) and are arranged in the second direction (X direction) at the first pitch p1, and the second line gratings 121 each have the length in the first direction (Y direction) and are arranged in the second direction (X direction) at the second pitch p2 different from the first pitch p1. The first line gratings 111 and the second line gratings 121 may have the same width, and among the first line gratings 111 and the second line gratings 121 of the first group G1, the first line grating 111 and the second line grating 121 that are located near the center portion may be disposed to be completely overlapped with each other in the third direction (Z direction). However, this is an example, and, the first line grating 111 and the second line grating 121 facing each other at different positions may be completely overlapped with each other. The location and number of the first line gratings 111 and the second line gratings 121 that overlap each other may be changed.

The alignment key 107 may further include a second group G2 adjacent to the first group G1. The second group G2 may be adjacent to the first group G1 in the second direction (X direction).

The second group G2 has a configuration obtained by rotating the first group G1 by 90° on a plane (X-Y plane) perpendicular to the third direction (Z direction). In other words, the second group G2 may also include the first line gratings 111 and the second line gratings 121, and the first line gratings 111 and the second line gratings 121 both have the length in the second direction (X direction) and are arranged in the first direction (Y direction) respectively at the first pitch p1 and the second pitch p2.

The alignment key 107 may further include a third group G3. The third group G3 is arranged adjacent to the first group G1 in a diagonal direction, and may have substantially the same configuration as the first group G1.

The alignment key 107 may further include a fourth group G4. The fourth group G4 is arranged adjacent to the second group G2 in a diagonal direction, and may have substantially the same configuration as the second group G2.

The alignment key 107 that is centrosymmetric as illustrated is provided to simultaneously measure overlays in the X direction and the Y direction.

The number of line gratings illustrated in each of the first to fourth groups G1, G2, G3, and G4 is an example and may be changed to 2 or more. The number of line gratings illustrated in each of the first to fourth groups G1, G2, G3, and G4 may be set such that a moiré pattern of one pitch or more appears.

The length, number, and the like of each of the first and second line gratings 111 and 121 may be determined such that the first to fourth groups G1, G2, G3, and G4 each have a square-shaped plan view. However, this is an example. The alignment key 107 may have a size of about 40 μm or less in each of the X and Y directions, but the disclosure is not limited thereto.

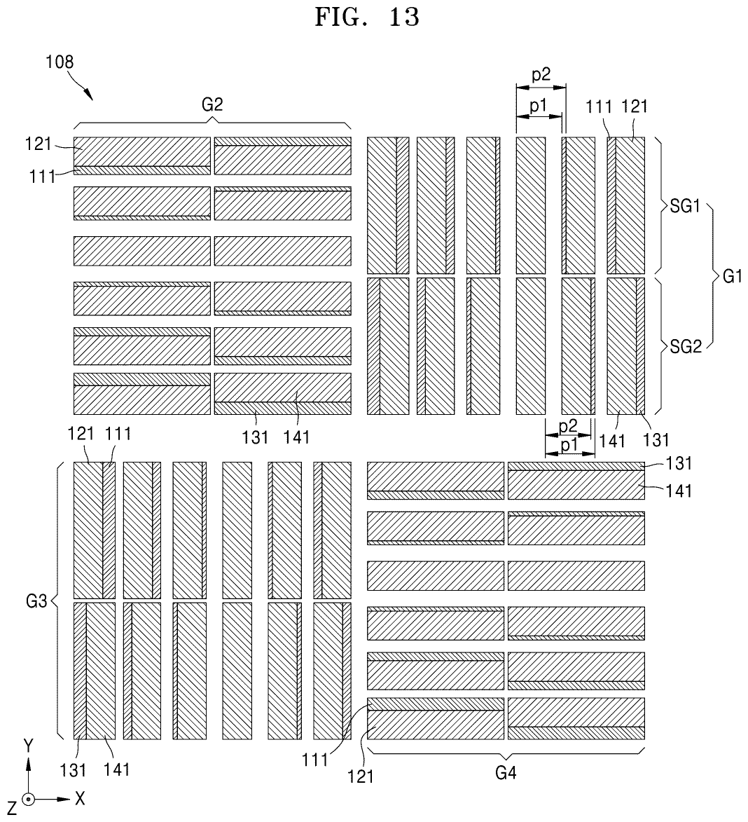

FIG. 13 is a plan view of an alignment key 108 according to one or more embodiments.

The alignment key 108 according to the present embodiment may be used for PBI or ADI, and in the drawing, while the configuration of the first substrate S1, the second substrate S2, and the dielectric layer 150 is omitted, only two pattern layers arranged to face each other in the third direction (Z direction) are illustrated. The two pattern layers may be referred to as an upper pattern layer and a lower pattern layer.

The alignment key 108 may include the first group G1, and the first group G1 may include a first subgroup SG1 and a second subgroup SG2.

The first subgroup SG1 may include, as illustrated in FIG. 1, a lower pattern layer including the first line gratings 111 and an upper pattern layer including the second line gratings 121. In other words, the first line gratings 111 may each have the length in the first direction (Y direction) and may be arranged in the second direction (X direction) at the first pitch p1, and the second line gratings 121 may each have the length in the first direction (Y direction) and may be arranged in the second direction (X direction) at the second pitch p2.

The second subgroup SG2 is arranged adjacent to the first subgroup SG1 in the first direction (Y direction). The second subgroup SG2 may include, similarly to the first subgroup SG1, a plurality of third line gratings 131 and a plurality of fourth line gratings 141, each having a longitudinal direction in the first direction (Y direction).

In other words, it may be described that the lower pattern layer of the first group G1 may further include the third line gratings 131 in addition to the first line gratings 111 of the first pattern layer 110 illustrated in FIG. 1, and the upper pattern layer of the first group G1 may further include the fourth line gratings 141 in addition to the second line gratings 121 of the second pattern layer 120 illustrated in FIG. 1.

The second subgroup SG2 has an arrangement pitch opposite to the first subgroup SG1. The third line gratings 131 constituting the lower pattern layer are regularly arranged in the second direction (X direction) at the second pitch p2, whereas the fourth line gratings 141 constituting the upper pattern layer are regularly arranged in the second direction (X direction) at the first pitch p1.

The alignment key 108 may further include the second group G2 adjacent to the first group G1.

The second group G2 has a configuration obtained by rotating the first group G1 by 90° on the plane (X-Y plane) perpendicular to the third direction (Z direction). In other words, while the second group G2 may include the first line gratings 111 and the third line gratings 131 constituting the lower pattern layer, and the second line gratings 121 and the fourth line gratings 141 constituting the upper pattern layer, the first to fourth line gratings 111, 121, 131, and 141 all have the length in the second direction (X direction), and the first line gratings 111 and the fourth line gratings 141 are arranged in the second direction (X direction) at the first pitch p1, and the second line gratings 121 and the third line gratings 131 are arranged in the second direction (X direction) at the second pitch p2.

The alignment key 108 may further include the third group G3. The third group G3 is arranged adjacent to the first group G1 in a diagonal direction, and has substantially the same configuration as the first group G1.

The alignment key 108 may further include the fourth group G4. The fourth group G4 is arranged adjacent to the second group G2 in a diagonal direction, and has substantially the same configuration as the second group G2.

As such, when there are the first group G1 including a pair of the first subgroup SG1 and the second subgroup SG2 measuring an overlay in the X direction, and likewise, the second group G2 including a pair of two subgroups measuring an overlay in the Y direction, the gain may be almost twice compared with the alignment key 100 of FIG. 1. In other words, a gain of (p1+p2)/|p1−p2| may be obtained.

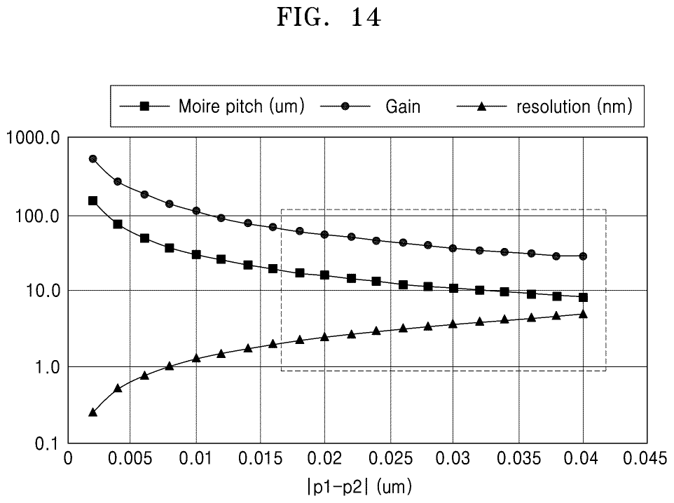

FIG. 14 is a graph showing an example of the performance of an alignment key according to one or more embodiments according to a difference between the pitch of a first pattern layer and the pitch of a second pattern layer.

The graph shows a moiré pattern pitch (moiré pitch), (p1*p2)/|p1−p2|, gain, and (p1+p2)/|p1−p2| according to |p1−p2|. A resolution shows an overlay measurement resolution when the alignment key and a microscope camera with a pixel resolution of 0.144 μm are used.

From the graph, considering a necessary precision and process condition, details of the alignment key may be designed. For example, a difference between the first pitch p1 and the second pitch p2, that is, a range of |p1−p2|, may be appropriately set within a region indicated by a dashed box. |p1−p2| may be 40 nm or less, 35 nm or less, or 25 nm or less. |p1−p2| may be 15 nm or more or 20 nm or more. However, this is an example, and, the disclosure is not limited thereto.

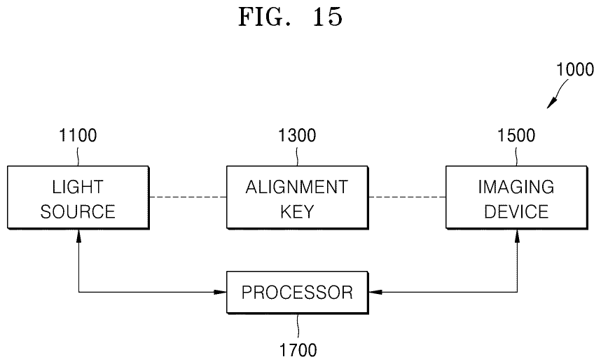

FIG. 15 is a schematic block diagram showing the structure of an inspection device 1000 according to one or more embodiments.

The inspection device 1000 may include a light source 1100, an alignment key 1300 on which light from the light source 1100 is incident, an imaging device 1500 that measures an optical interference pattern (e.g., a moiré pattern) formed after the light incident on the alignment key 1300 passes through the alignment key 1300, and a processor 1700 that analyzes a measurement result of the imaging device 1500.

The light source 1100 may provide light having a wavelength in a range of about 1.1 μm to 1.3 μm. However, the disclosure is not limited thereto. The light source 1100 may emit parallel light to the alignment key 1300. The light source 1100 may include various types of light sources, and may further include an additional optical element to form parallel light.

The alignment key 1300 may include any one of the alignment keys 100 to 108 according to the embodiments described above, a combination thereof, or a modified alignment key.

The two pattern layers provided in the alignment key 1300 may be divided and arranged in two substrates subject to bonding, and whether device layers to be combined in the two substrates are aligned may be inspected.

Alternatively, the two pattern layers provided in the alignment key 1300 may be disposed in one substrate, and whether a pattern formed on the substrate in a photolithography process and another pattern thereunder are aligned with each other may be inspected.

The imaging device 1500 may capture an image of a moiré pattern formed as the light emitted from the light source 1100 passes through the alignment key 1300. The imaging device 1500 may be implemented as a digital camera, a microscope camera, a scanner, a charge coupled device (CCD) sensor, a complementary metal oxide semiconductor (CMOS) sensor, or an interferometer.

The processor 1700 may analyze whether the device layers provided in the substrate subject to inspection are aligned, based on a measurement result of the imaging device 1500. The processor 1700 may be a hardware component or an integrated circuit that is capable of executing instructions stored in memory to perform various operations, including arithmetic, logic, control, and input/output (I/O) operations. The processor 1700 may include one or more processing units, such as a central processing unit (CPU), a graphics processing unit (GPU), a digital signal processor (DSP), or a combination thereof.

The alignment key 1300 has a very large gain that amplifies an alignment error to a moiré pattern movement, and thus, accuracy in the overlay measurement may be improved.

The alignment key described above has a high gain that amplifies an alignment error to a moiré pattern movement, and thus, precision in the overlay measurement may be improved.

The two pattern layers provided in the alignment key described above may be divided and arranged in two substrates to be bonded, and may be used for post bonding inspection after the two substrates bonded to each other.

The two pattern layers provided in the alignment key described above may be disposed on one substrate, and may be used for after development inspection, after the photolithography process.

The foregoing exemplary embodiments are merely exemplary and are not to be construed as limiting. The present teaching can be readily applied to other types of apparatuses. Also, the description of the exemplary embodiments is intended to be illustrative, and not to limit the scope of the claims, and many alternatives, modifications, and variations will be apparent to those skilled in the art.

What is claimed is:

1. An alignment key configured to form an optical interference pattern by using incident light, the alignment key comprising:
a first substrate;
a first pattern layer comprising a plurality of first gratings disposed on the first substrate, wherein the plurality of first gratings are regularly arranged at a first pitch that is less than a wavelength of the incident light; and
a second pattern layer disposed to face the first pattern layer and comprising a plurality of second gratings, wherein the plurality of second gratings are regularly arranged at a second pitch that is different from the first pitch and less than the wavelength of the incident light, in a same arrangement direction as the plurality of first gratings.

2. The alignment key of claim 1, wherein each of the plurality of first gratings and the plurality of second gratings is a line grating that extends linearly in a direction perpendicular to the arrangement direction of the plurality of first gratings and the plurality of second gratings,
wherein the first pitch of the plurality of first gratings and the second pitch of the plurality of second gratings are each equal to or less than ½ of the wavelength of the incident light.

3. The alignment key of claim 1, wherein a width of each of the plurality of first gratings in the second direction is same as a width of each of the plurality of second gratings in the second direction.

4. The alignment key of claim 1, wherein the first substrate comprises grooves recessed from a surface of the first substrate and corresponding to a reverse shape of the plurality of first gratings, and the plurality of first gratings are disposed within the grooves.

5. The alignment key of claim 1, wherein the plurality of first gratings or the plurality of second gratings comprise a metal material.

6. The alignment key of claim 1, wherein the plurality of second gratings are disposed on a second substrate having one surface in contact with the first substrate.

7. The alignment key of claim 6, wherein the second substrate comprises grooves recessed from the one surface and corresponding to a reverse shape of the plurality of second gratings, and the plurality of second gratings are disposed within the grooves.

8. The alignment key of claim 6, wherein the plurality of second gratings are entirely buried inside the second substrate.

9. The alignment key of claim 8, wherein a distance which the plurality of second gratings are separated from the one surface is λ/(2*n) or less, where λ is the wavelength of the incident light and n is a refractive index of the second substrate.

10. The alignment key of claim 8, further comprising a metastructure layer disposed between the plurality of second gratings and the one surface and comprising a plurality of nanostructures.

11. The alignment key of claim 10, wherein each of the plurality of nanostructures has a cylindrical shape with a diameter less than a width of each of the plurality of first gratings and each of the plurality of second gratings.

12. The alignment key of claim 10, wherein an arrangement pitch of the plurality of nanostructures is less than each of the first pitch and the second pitch.

13. The alignment key of claim 1, wherein the second pattern layer is supported by the first substrate and disposed apart from the first pattern layer.

14. The alignment key of claim 13, further comprising a dielectric layer disposed between the first pattern layer and the second pattern layer.

15. The alignment key of claim 13, wherein the first pattern layer is buried to a certain depth from one surface of the first substrate, and
the second pattern layer is disposed on the one surface.

16. The alignment key of claim 13, wherein each of the plurality of first gratings comprises a metal material, and
each of the plurality of second gratings comprises a photoresist material.

17. The alignment key of claim 1, wherein each of the plurality of first gratings and the plurality of second gratings extends linearly in a first direction, the plurality of first gratings are repeatedly arranged in a second direction perpendicular to the first direction, and the first pattern layer and the second pattern layer are disposed to face each other is a third direction perpendicular to the first direction and the second direction,
based on the first pattern layer and the second pattern layer facing each other in the third direction being a first group, the alignment key further comprises a second group adjacent to the first group in the first direction or the second direction, and
the second group has a configuration obtained by rotating the first group by 90° on a plane perpendicular to the third direction.

18. The alignment key of claim 1, wherein each of the plurality of first gratings and the plurality of second gratings extends linearly in a first direction, the plurality of first gratings are repeatedly arranged in a second direction perpendicular to the first direction, and the first pattern layer and the second pattern layer are disposed to face each other is a third direction perpendicular to the first direction and the second direction,
the first pattern layer further comprises a plurality of third line gratings each having a longitudinal direction in the first direction, and regularly arranged in the second direction at the second pitch, and
the second pattern layer further comprises a plurality of fourth gratings each having a longitudinal direction in the first direction, and regularly arranged in the second direction at the first pitch.

19. The alignment key of claim 18, wherein, based on the first pattern layer and the second pattern layer facing each other in the third direction being a first group, the alignment key further comprises a second group adjacent to the first group in the first direction or the second direction, and
the second group has a configuration obtained by rotating the first group by 90° on a plane perpendicular to the third direction.

20. An inspection device comprising:
a light source;
an alignment key on which light emitted from the light source is incident;
an imaging device configured to measure an optical interference pattern formed through an interaction between the light and the alignment key; and
a processor configured to analyze a measurement result of the imaging device,
wherein the alignment key comprises a top bonding plate and a bottom bonding plate, each of the top bonding plate and the bottom bonding plate comprising a plurality of metal-based gratings, and
wherein the plurality of metal-based gratings on the top bonding plate has a first pitch, and plurality of metal-based gratings on the bottom bonding plate has a second pitch, the first pitch and the second pitch being different from each other and each of the first pitch and the second pitch being less than half a wavelength of the incident light.
